(19) United States
(12) Patent Application Publication
(10) Pub. No.: US 2026/0205112 A1
(43) Pub. Date: Jul. 16, 2026

(54) GATE DRIVER CIRCUIT, MOTOR DRIVER, AND ELECTRONIC DEVICE

(71) Applicant: ROHM CO., LTD., Kyoto (JP)

(72) Inventors: Hiroki SUGAMOTO, Kyoto (JP); Yusuke ANZAI, Kyoto (JP)

(21) Appl. No.: 19/444,703

(22) Filed: Jan. 9, 2026

(30) Foreign Application Priority Data
Jan. 16, 2025 (JP) 2025-006353

(51) Int. Cl. H03K 17/687; H02P 27/06

(52) U.S. Cl. CPC H03K 17/6871; H02P 27/06; H03K 2217/0063; H03K 2217/0072

(57) ABSTRACT

A gate driver circuit, which drives a switching circuit including a high-side transistor and a low-side transistor, includes: a bootstrap terminal connected to a capacitor; a high-side gate terminal connected to a gate of the high-side transistor; a low-side gate terminal connected to a gate of the low-side transistor; a switching terminal connected to an output of the switching circuit; a bootstrap switch connected to the bootstrap terminal; a high-side driver including power supply terminals connected to the terminals and generating a high-side gate voltage in response to a high-side control signal; a low-side driver which generates a low-side gate voltage in response to a low-side control signal; a sensor which asserts a detection signal when the high-side transistor or the low-side transistor is electrically changed; and a control circuit which generates the high-side and low-side control signals and turns on the bootstrap switch in response to the detection signal.

### CROSS REFERENCE TO RELATED APPLICATION

The present invention claims priority under 35 U.S.C. § 119 to Japanese Patent Application No. 2025-006353, filed on Jan. 16, 2025, the entire content of which is incorporated herein by reference.

### TECHNICAL FIELD

The present disclosure relates to a gate driver circuit.

### BACKGROUND

In the related art, an output stage of a motor driver circuit is constituted by a switching circuit such as an H-bridge circuit or a three-phase inverter.

A leg of the switching circuit includes an upper arm provided between an input line IN and an output line OUT, and a lower arm provided between the output line OUT and a ground line. When a transistor in the upper arm is configured as an N-type transistor, that is, an N-channel field-effect transistor (FET), an NPN-type bipolar transistor, or an IGBT, a bootstrap circuit is used.

The bootstrap circuit includes a bootstrap capacitor including one end connected to the output line, and a rectifier element (diode) that applies a constant voltage to the other end of the bootstrap capacitor. A bootstrap voltage V_{BST}, which is higher than an output voltage (switching voltage) generated on the output line by V_{REG}−V_{f}, is generated at the other end of the bootstrap capacitor.

$${V}_{BST} = {V}_{OUT} + {V}_{REG} - {V}_{f}$$

As a switching frequency or a duty cycle increases, a period of low output during which V_{OUT}=0 V becomes shorter. Thus, a charging time of the bootstrap capacitor becomes shorter, and the bootstrap capacitor is unable to store a sufficient amount of electrical charge. When the charging voltage is insufficient, the power transistor of the upper arm cannot be turned on, causing problems in circuit operation.

### BRIEF DESCRIPTION OF DRAWINGS

The accompanying drawings, which are incorporated in and constitute a part of the specification, illustrate embodiments of the present disclosure.

FIG. 1 is a circuit diagram of a switching circuit according to a comparative technology.

FIG. 2 is a waveform diagram illustrating an operation of the switching circuit shown in FIG. 1.

FIG. 3 is a circuit diagram of a switching circuit according to an embodiment.

FIG. 4 is a waveform diagram illustrating an operation of the switching circuit according to the embodiment.

FIG. 5 is a diagram illustrating a modification of control of a bootstrap switch.

FIG. 6 is a circuit diagram of a motor driver according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### SUMMARY OF EMBODIMENT

A summary of some exemplary embodiments of the present disclosure will be described. This summary is intended to provide a simplified description of some concepts of one or more embodiments in order to provide a basic understanding of the embodiments as a prelude to the following detailed description, and is not intended to limit the breadth of the disclosure. Further, this summary is not an exhaustive overview of all conceivable embodiments and is not intended to limit essential components of the embodiments. For the sake of convenience, “one embodiment” may be used to refer to one embodiment (example or modification) or multiple embodiments (examples or modifications) described in this specification.

A gate driver circuit according to one embodiment drives a switching circuit including an N-type high-side transistor and an N-type low-side transistor in response to an input signal. The gate driver circuit includes: a bootstrap terminal to which one end of a bootstrap capacitor is connected; a high-side gate terminal to which a gate of the high-side transistor is connected; a low-side gate terminal to which a gate of the low-side transistor is connected; a switching terminal to which an output line of the switching circuit is connected; a bootstrap switch connected to the bootstrap terminal at one end and configured to receive a constant voltage at the other end; a high-side driver having an upper power supply terminal connected to the bootstrap terminal and a lower power supply terminal connected to the switching terminal, and configured to generate a high-side gate voltage at the high-side gate terminal in response to a high-side control signal; a low-side driver configured to generate a low-side gate voltage at the low-side gate terminal in response to a low-side control signal; a first sensor configured to assert a first detection signal upon detecting a change in an electrical state of a first transistor, which is one of the high-side transistor and the low-side transistor, based on a gate voltage of the first transistor; and a control circuit configured to generate the high-side control signal and the low-side control signal in response to the input signal and configured to turn on the bootstrap switch in response to the assertion of the first detection signal.

In the gate driver circuit, from a timing at which the input signal changes, a timing at which the gate voltage of the high-side transistor or the low-side transistor changes is delayed, and a timing at which the output voltage of the switching circuit changes is further delayed. When the input signal is used to control the bootstrap switch when the output voltage transitions from a high voltage to a low voltage, the bootstrap switch is turned on while the output voltage is still high, and thus, the bootstrap capacitor is discharged. This unnecessary discharge results in an insufficient voltage on the bootstrap capacitor, and the high-side transistor cannot be turned on.

In the embodiment described above, the first sensor is provided such that the bootstrap switch is turned on when the electrical state of the first transistor actually changes. Therefore, a period during which electrical charges are discharged from the bootstrap capacitor can be shortened, and the high-side transistor can be turned on reliably.

In one embodiment, the gate driver circuit may further include a second sensor configured to assert a second detection signal upon detecting a change in an electrical state of a second transistor, which is one of the high-side transistor and the low-side transistor, based on a gate voltage of the second transistor. The control circuit may turn off the bootstrap switch in response to the assertion of the second detection signal.

When the input signal is used to control the bootstrap switch when the output voltage transitions from a low voltage to a high voltage, the bootstrap switch is turned off while the output voltage is a low voltage, and thus, the bootstrap capacitor, although in a chargeable state, is not charged.

In the embodiment described above, the second sensor is provided such that the bootstrap switch is turned off when the electrical state of the second transistor actually changes. Therefore, a period during which the bootstrap capacitor is charged can be extended as long as possible, and thus, the high-side transistor can be turned on reliably.

In one embodiment, the first sensor may compare a gate-source voltage of the low-side transistor with a first threshold voltage.

In one embodiment, the second sensor may compare a gate-source voltage of the low-side transistor with a second threshold voltage.

In one embodiment, the first sensor may compare a gate-source voltage of the high-side transistor with a first threshold voltage.

In one embodiment, the second sensor may compare a gate-source voltage of the high-side transistor with a second threshold voltage.

In one embodiment, the first sensor may compare a drain-source voltage of the low-side transistor with a first threshold voltage.

In one embodiment, the second sensor may compare a drain-source voltage of the low-side transistor with a second threshold voltage.

In one embodiment, the first sensor may compare a drain-source voltage of the high-side transistor with a first threshold voltage.

In one embodiment, the second sensor may compare a drain-source voltage of the high-side transistor with a second threshold voltage.

A motor driver according to one embodiment may include: a switching circuit including a high-side transistor and a low-side transistor; and the gate driver circuit described above configured to drive the switching circuit.

An electronic device according to one embodiment may include: a motor; and the motor driver described above configured to drive the motor.

### Embodiment

Preferred embodiments will be described below with reference to the drawings. Identical or equivalent components, members, and processes shown in each drawing are designated by same reference numerals, and redundant descriptions thereof will be omitted where appropriate. Furthermore, the embodiments are exemplary and are not intended to limit the present disclosure. All features and combinations thereof described in the embodiments are not necessarily essential to the present disclosure.

In the present disclosure, “a state where a member A is connected to a member B” includes a case where the member A and the member B are physically directly connected and also includes a case where the member A and the member B are indirectly connected via another member that does not affect a state of electrical connection between the members A and B or does not impair functions or effects achieved by coupling the members A and B.

Similarly, “a state where a member C is provided between a member A and a member B” includes a case where the members A and C or the members B and C are directly connected, and also includes a case where the members A and C or the members B and C are indirectly connected via another member that does not affect a state of electrical connection between the members A and C or the members B and C or does not impair functions or effects achieved by coupling the members A and C or the members B and C.

Vertical and horizontal axes in waveform diagrams and time charts referred to in this specification are appropriately enlarged or reduced to facilitate understanding. In addition, waveforms shown are simplified, exaggerated, or emphasized to facilitate understanding.

Before describing a gate driver according to the embodiment, problems occurring in a gate driver circuit will be described with reference to a comparative technology.

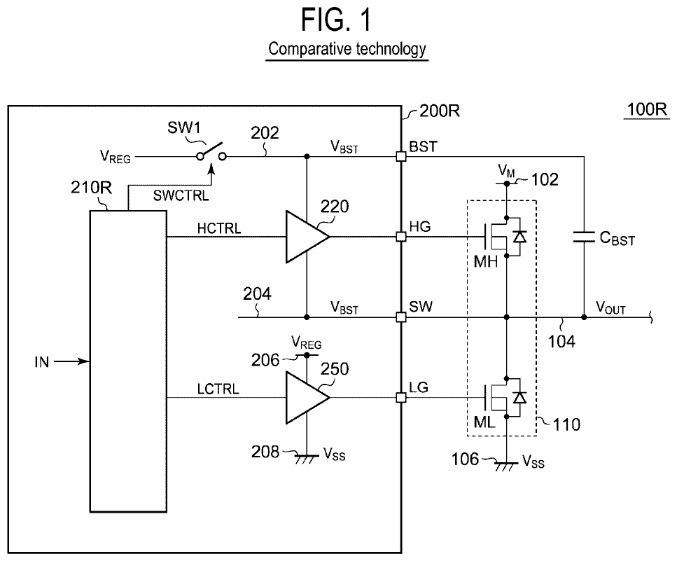

FIG. 1 is a circuit diagram of a switching circuit 100R according to a comparative technology. The switching circuit 100R includes a bridge circuit 110 and a gate driver circuit 200R. Although a configuration of only one phase of the switching circuit 100R is shown here, the switching circuit 100R may be a three-phase circuit or an H-bridge circuit.

The bridge circuit 110 includes a high-side transistor MH provided between a power supply line (input line) 102 and an output terminal (output line) 104, and a low-side transistor ML provided between the output line 104 and a ground line 106. An input voltage V_{M} is supplied to the input line 102. In the present embodiment, the high-side transistor MH and the low-side transistor ML are N-channel MOSFETs, and respective body diodes thereof also function as flywheel diodes.

The gate driver circuit 200R drives the high-side transistor MH and the low-side transistor ML of the bridge circuit 110.

A bootstrap capacitor C_{BST} is connected between a bootstrap pin BST and the output line 104. A high-side gate pin HG is connected to a gate of the high-side transistor MH. A switching pin SW is connected to a source of the high-side transistor MH and a drain of the low-side transistor ML. A low-side gate pin LG is connected to a gate of the low-side transistor ML.

A bootstrap line 202 is connected to the bootstrap pin BST. The bootstrap line 202 is provided with a bootstrap switch SW1 that can be switched on and off in response to a control signal SWCTRL.

During a period in which the bootstrap switch SW1 is turned on, a constant voltage V_{REG} is applied to the bootstrap line 202. The bootstrap switch SW1 and the bootstrap capacitor C_{BST} form a bootstrap circuit, which maintains a voltage V_{BST} of the bootstrap line 202 at V_{OUT}+VREG−V_{ON}, where V_{ON} is a voltage drop across the bootstrap switch SW1.

The gate driver circuit 200R is a functional IC integrated on a single semiconductor substrate, and includes a control circuit 210R, a high-side driver 220, and a low-side driver 250. The high-side driver 220 includes an upper power supply terminal connected to the bootstrap line 202 and a lower power supply terminal connected to a switching line 204, and outputs a high voltage V_{BST} or a low voltage V_{OUT} in response to a high-side control signal HCTRL input to the high-side driver 220.

The low-side driver 250 includes an upper power supply terminal connected to a constant voltage line 206 and an output power supply terminal connected to a ground line 208, and outputs a high voltage V_{REG} or a low voltage V_{SS} in response to a low-side control signal LCT RL input to the low-side driver 250.

The control circuit 210R controls the high-side driver 220 and the low-side driver 250 in response to an input signal IN. When the input signal IN is at a first level (e.g., high), the control circuit 210R generates a high-side control signal HCTRL so that the high-side driver 220 outputs a high voltage (V_{BST}), and generates a low-side control signal LCTRL so that the low-side driver 250 outputs a low voltage (ground voltage V_{SS}=0 V). As a result, the high-side transistor MH is turned on and the low-side transistor ML is turned off, and the bridge circuit 110 enters a high-output state (output voltage V_{OUT}=V_{M}).

When the input signal IN is at a second level (e.g., low), the control circuit 210R generates a high-side control signal HCTRL so that the high-side driver 220 outputs a low voltage (V_{OUT}), and generates a low-side control signal LCTRL so that the low-side driver 250 outputs a high voltage (V_{REG}). As a result, the high-side transistor MH is turned off, the low-side transistor ML is turned on, and the bridge circuit 110 enters a low-output state (output voltage V_{OUT}=V_{SS}).

When the input signal IN transitions from the first level (high) to the second level (low), the control circuit 210R causes the high-side driver 220 to operate in a current sink mode, decreases a gate-source voltage V_{GS(H)} of the high-side transistor MH toward 0 V, and turns off the high-side transistor MH. Upon detecting that the high-side transistor MH is turned off, the control circuit 210R causes the low-side driver 250 to operate in a current source mode, increases a gate-source voltage V_{GS(L)} of the low-side transistor ML, and turns on the low-side transistor ML.

Conversely, when the input signal IN transitions from the second level (low) to the first level (high), the control circuit 210R causes the low-side driver 250 to operate in the current sink mode, decreases the gate-source voltage V_{GS(L)} of the low-side transistor ML toward 0 V, and turns off the low-side transistor ML. Upon detecting that the low-side transistor ML is turned off, the control circuit 210R causes the high-side driver 220 to operate in the current source mode, increases the gate-source voltage V_{GS(H)} of the high-side transistor MH, and turns on the high-side transistor MH.

In the comparative technology, the control circuit 210R controls the bootstrap switch SW1 in response to the input signal IN. Specifically, the control signal SWCTRL is generated so that when the input signal IN is at the first level (high), the bootstrap switch SW1 is turned off, and when the input signal IN is at the second level (low), the bootstrap switch SW1 is turned on.

A configuration of the switching circuit 100R according to the comparative technology has been described above. Next, an operation of the switching circuit 100R will be described.

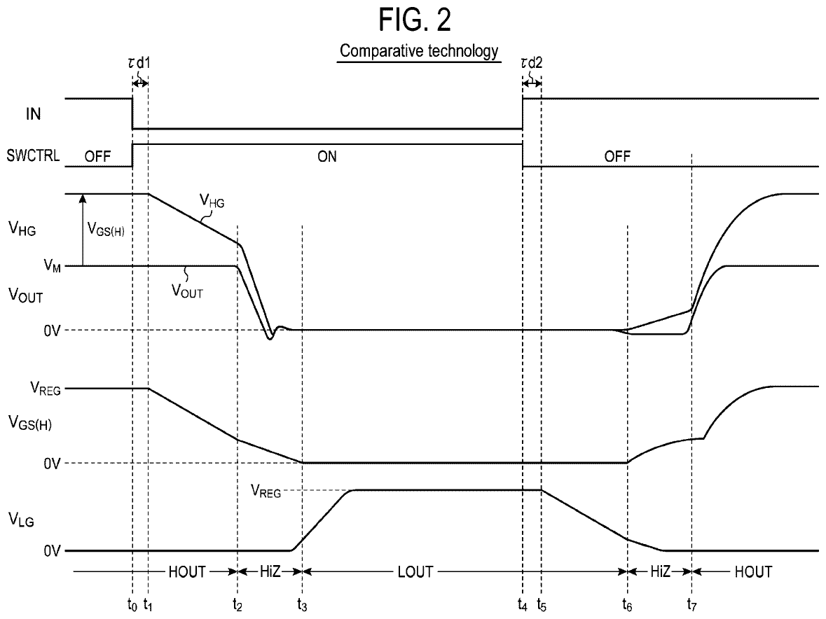

FIG. 2 is a waveform diagram of the operation of the switching circuit 100R shown in FIG. 1. Here, the operation of the switching circuit 100R in the current source mode, that is, an operation of sourcing a current from the bridge circuit 110 to a load, will be described.

Before time t0, the input signal IN is at the first level (high), the high-side transistor MH is turned on, the low-side transistor ML is turned off, and the output voltage V_{OUT} is at a high voltage V_{M} (high-output state HOUT).

At time t0, the input signal IN is changed from a first level (high) to a second level (low). Due to the influence of a control delay in the control circuit 210R and a propagation delay in the high-side driver 220, at time t1, which is τd1 after time t0, a gate voltage V_{HG} of the high-side transistor MH begins to decrease and the gate-source voltage V_{GS(H)} decreases. As the gate-source voltage V_{GS(H)} decreases, a voltage drop across the high-side transistor MH increases, and the output voltage V_{OUT} decreases over time.

At time t2, when the gate-source voltage V_{GS(H)} of the high-side transistor MH becomes lower than a gate threshold voltage V_{GS(th)} of a MOSFET, the high-side transistor MH is turned off. At this time, the bridge circuit 110 enters a high-impedance state HiZ (dead time).

When the turn-off of the high-side transistor MH is detected, the gate-source voltage V_{GS(L)} of the low-side transistor ML rises, and when the gate-source voltage V_{GS(L)} exceeds the gate threshold voltage V_{GS(th)} at time t3, the low-side transistor ML is turned on. After time t3, a low-output state (LOUT) is achieved.

At time t4, the input signal IN is changed from the second level (low) to the first level (high). Due to the influence of the control delay in the control circuit 210R and a propagation delay in the low-side driver 250, at time t5, which is τd2 after time t4, a gate voltage V_{LG} of the low-side transistor ML (i.e., the gate-source voltage V_{GS(L)}) begins to decrease.

At time t6, when the gate-source voltage V_{GS(L)} of the low-side transistor ML becomes lower than the gate threshold voltage V_{GS(th)} of the MOSFET, the low-side transistor ML is turned off, and the bridge circuit 110 enters the high-impedance state HiZ.

When the turn-off of the low-side transistor ML is detected, the gate-source voltage V_{GS(H)} of the high-side transistor MH rises, and when the gate-source voltage V_{GS(H)} exceeds the gate threshold voltage V_{GS(th)} at time t7, the high-side transistor MH is turned on. After time t7, the high-output state HOUT is achieved.

Next, control of the bootstrap switch SW1 will be described. In the comparative technology, the bootstrap switch SW1 is controlled in conjunction with the input signal IN. That is, when the input signal IN is at the first level (high), the bootstrap switch SW1 is turned off, and when the input signal IN is at the second level (low), the bootstrap switch SW1 is turned on.

Focusing on a period from t0 to t2, the output voltage V_{OUT} is at the high voltage V_{M}. Therefore, a relationship of V_{REG}<V_{BST} holds. In the comparative technology, during the period t0 to t2, the bootstrap switch SW1 is turned on and the bootstrap capacitor C_{BST} is discharged via the bootstrap switch SW1. In a situation where a switching frequency is high or a duty cycle is large, the unnecessary discharge during the period t0 to t2 leads to an insufficient voltage across the bootstrap capacitor C_{BST}, and the high-side transistor MH cannot be turned on.

Focusing on a period from t4 to t6, the output voltage V_{OUT} is at the low voltage V_{SS} (=0 V). Therefore, during this period, the bootstrap capacitor C_{BST} can be charged. However, in the comparative technology, the bootstrap switch SW1 is turned off during the period t4 to t6, and charging does not occur. In the situation where the switching frequency is high or the duty cycle is large, the non-charging period from t4 to t6 causes an insufficient voltage across the bootstrap capacitor C_{BST}, and the high-side transistor MH cannot be turned on.

Problems that arise in the comparative technology have been described. Next, a switching circuit 100 according to an embodiment will be described.

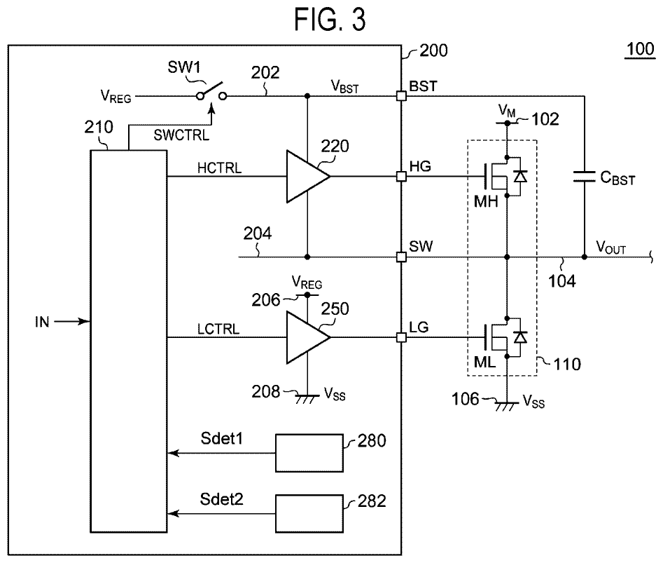

FIG. 3 is a circuit diagram of a switching circuit 100 according to the embodiment. A gate driver circuit 200 according to the embodiment includes a first sensor 280 and a second sensor 282 in addition to the gate driver circuit 200R shown in FIG. 1.

The first sensor 280 monitors an electrical state of a transistor (referred to as a first transistor) to be monitored, which is one of the high-side transistor MH and the low-side transistor ML, based on a gate voltage of the transistor. Upon detecting a change in the electrical state, the first sensor 280 asserts a first detection signal Sdet1. The electrical state monitored based on the gate voltage of the transistor may be a gate-source voltage or a drain-source voltage of the transistor.

The second sensor 282 monitors an electrical state of a transistor (referred to as a second transistor) to be monitored, which is one of the high-side transistor MH and the low-side transistor ML, based on a gate voltage of the transistor. Upon detecting a change in the electrical state, the second sensor 282 asserts a second detection signal Sdet2.

The first transistor monitored by the first sensor 280 and the second transistor monitored by the second sensor 282 may be the same transistor or may be different transistors.

After the input signal IN is changed from the first level to the second level, the control circuit 210 turns on the bootstrap switch SW1 in response to the assertion of the first detection signal Sdet1.

Further, after the input signal IN is changed from the second level to the first level, the control circuit 210 turns off the bootstrap switch SW1 in response to the assertion of the second detection signal Sdet2.

In one embodiment, the first transistor monitored by the first sensor 280 and the second transistor monitored by the second sensor 282 are both the low-side transistor ML.

The first sensor 280 compares the gate-source voltage V_{GS(L)} of the low-side transistor ML with a first threshold voltage V_{TH1}, and asserts the first detection signal Sdet1 when V_{GS(L)}>V_{TH1}.

The second sensor 282 compares the gate-source voltage V_{GS(L)} of the low-side transistor ML with a second threshold voltage V_{TH2}, and asserts the second detection signal Sdet2 when V_{GS(L)}<V_{TH2}. The first threshold voltage V_{TH1} and the second threshold voltage V_{TH2} may be set equal to each other, in which case the first sensor 280 and the second sensor 282 may be a common sensor.

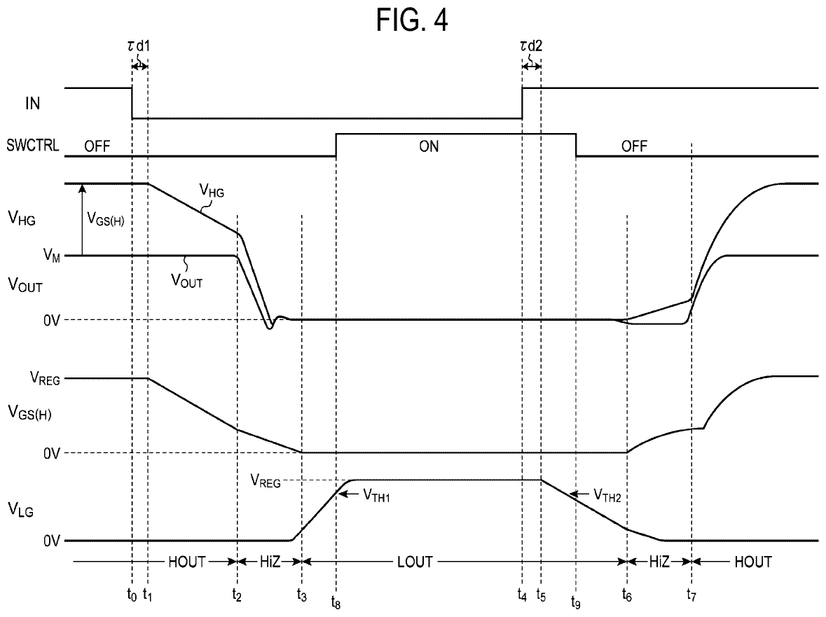

FIG. 4 is a waveform diagram of an operation of the switching circuit 100 according to the embodiment. Except for a control of the bootstrap switch SW1, the operation is the same as in FIG. 2.

In the present embodiment, at time t8, when the gate-source voltage V_{GS(L)} of the low-side transistor ML exceeds the first threshold voltage V_{TH1}, the bootstrap switch SW1 is turned on. At time t9, when the gate-source voltage V_{GS(L)} of the low-side transistor ML becomes lower than the second threshold voltage V_{TH2}, the bootstrap switch SW1 is turned off.

The operation of the switching circuit 100 has been described above. According to the switching circuit 100, a timing at which the bootstrap switch SW1 is turned on is delayed compared to that of the comparative technology. Specifically, since the bootstrap switch SW1 is turned on after the output voltage V_{OUT} drops to a low voltage, the discharge of the bootstrap capacitor C_{BST} can be suppressed.

Further, according to the switching circuit 100, a timing at which the bootstrap switch SW1 is turned off is delayed compared to that of the comparative technology. Therefore, the bootstrap capacitor C_{BST} can be charged for a longer period of time compared to the comparative technology.

Next, a modification of the control of the bootstrap switch SW1 will be described.

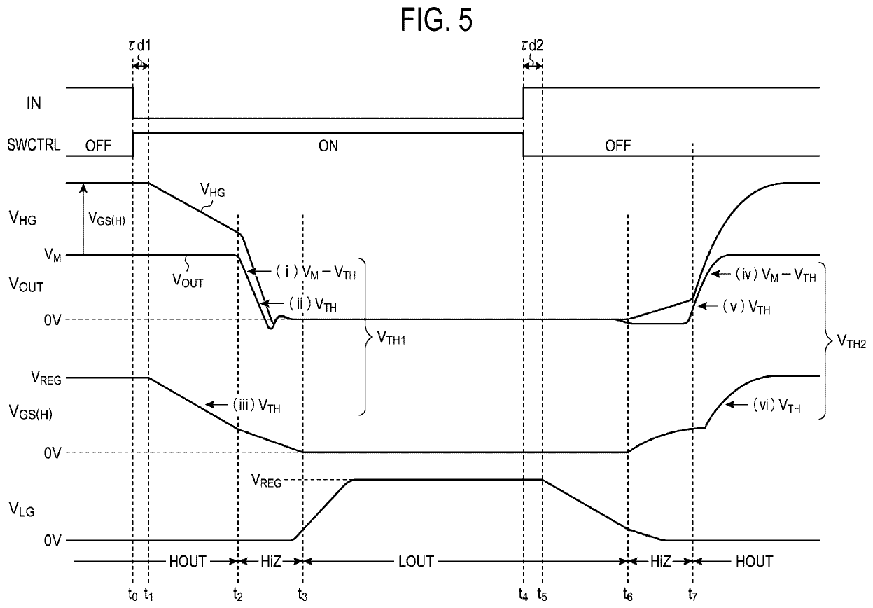

FIG. 5 is a diagram illustrating the modification of the control of the bootstrap switch SW1.

Modifications regarding the timing at which the bootstrap switch SW1 is turned on will be described.

### (i) Modification 1

The first sensor 280 may monitor a drain-source voltage V_{DS(H)} of the high-side transistor MH and may assert the first detection signal Sdet1 when V_{DS(H)}>V_{TH1}. In other words, the first sensor 280 may monitor the output voltage V_{OUT} and may assert the first detection signal Sdet1 when V_{OUT}<V_{M}−V_{TH1}.

### (ii) Modification 2

The first sensor 280 may monitor a drain-source voltage V_{DS(L)} of the low-side transistor ML and may assert the first detection signal Sdet1 when V_{DS(L)}<V_{TH1}. In other words, the first sensor 280 may monitor the output voltage V_{OUT} and may assert the first detection signal Sdet1 when V_{OUT}<V_{TH1}.

(iii) Modification 3

The first sensor 280 may monitor the gate-source voltage V_{GS(H)} of the high-side transistor MH and may assert the first detection signal Sdet1 when V_{GS(H)}<V_{TH1}.

A modification regarding the timing at which the bootstrap switch SW1 is turned off will be described.

### (iv) Modification 4

The second sensor 282 may monitor the drain-source voltage V_{DS(H)} of the high-side transistor MH and may assert the second detection signal Sdet2 when V_{DS(H)}<V_{TH2}. In other words, the second sensor 282 may monitor the output voltage V_{OUT} and may assert the second detection signal Sdet2 when V_{OUT}<V_{M}−V_{TH2}.

### (v) Modification 5

The second sensor 282 may monitor the drain-source voltage V_{DS(L)} of the low-side transistor ML and may assert the second detection signal Sdet2 when V_{DS(L)}>V_{TH2}. In other words, the second sensor 282 may monitor the output voltage V_{OUT} and may assert the second detection signal Sdet2 when V_{OUT}>V_{TH2}.

### (vi) Modification 6

The second sensor 282 may monitor the gate-source voltage V_{GS(H)} of the high-side transistor MH and may assert the second detection signal Sdet2 when V_{GS(H)}>V_{TH2}.

The control of turning the bootstrap switch SW1 on and off may be arbitrarily combined with those described in the embodiment and modifications.

### Applications

Next, applications of the switching circuit 100 will be described. The switching circuit 100 may be suitably used in a motor drive circuit.

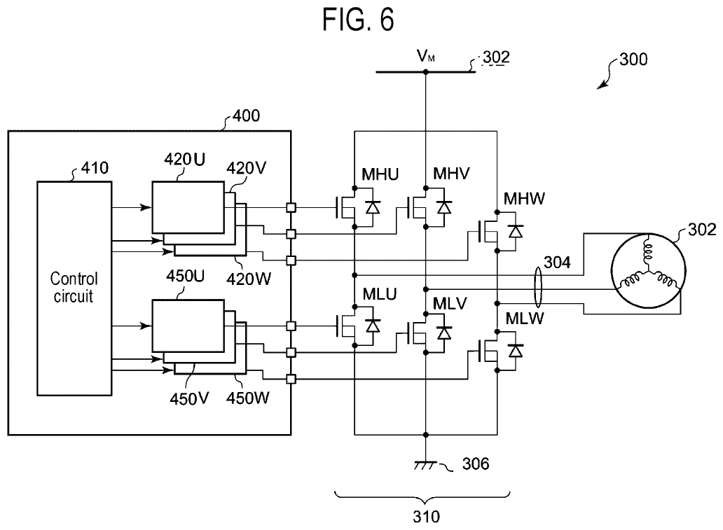

FIG. 6 is a circuit diagram of a motor driver 300 according to an embodiment of the present disclosure. The motor driver 300 drives a three-phase motor 302, which is a load, to control a state of rotation of the three-phase motor 302.

The motor driver 300 includes a bridge circuit 310 and a gate driver circuit 400. The bridge circuit 310 is a three-phase inverter and includes U-phase, V-phase, and W-phase legs. Each phase leg includes a high-side transistor MH and a low-side transistor ML.

The gate driver circuit 400 includes a control circuit 410, high-side drivers 420U, 420V, and 420W, and low-side drivers 450U, 450V, and 450W. The control circuit 410 generates control signals indicating states of six arms that constitute the bridge circuit 310 based on the state of the three-phase motor 302, which is the load.

The high-side drivers 420U, 420V, and 420W are configured with an architecture of the high-side driver 220 described above. The low-side drivers 450U, 450V, and 450W are also configured with the architecture of the low-side driver 250 described above.

Although a three-phase motor is used as an example here, a single-phase motor may also be used, in which case the bridge circuit 310 becomes an H-bridge circuit.

Next, applications of the motor driver 300 will be described. The motor driver 300 can be used to control a spindle motor of a hard disk or a lens drive motor of an imaging device. Alternatively, the motor driver 300 can be used to drive a printer head drive motor or a paper feed motor. Alternatively, the motor driver 300 can be used to drive motors in electric vehicles, hybrid vehicles, or the like.

The embodiments are merely examples. It will be understood by those skilled in the art that various modifications are possible by combining the respective components and processing steps, and that such modifications are also within the scope of the present disclosure. Such modifications will be described below.

### (Modification 1)

In the embodiment, the bridge circuit 110 is constituted by discrete components. However, the present disclosure is not limited thereto, and the bridge circuit 110 may be integrated into the gate driver circuit 200.

### (Modification 2)

The high-side and low-side transistors may be constituted by insulated gate bipolar transistors (IGBTs).

### (Modification 3)

The applications of the switching circuit 100 is not limited to the motor driver 300. For example, the switching circuit 100 may be suitably used in switching regulators (DC/DC converters), various power converters (inverters and converters), inverters for lighting discharge lamps, digital audio amplifiers, and the like. Therefore, the switching circuit 100 may be used in consumer devices including electronic devices and home appliances, automobiles, in-vehicle components, industrial vehicles, and industrial machinery.

The embodiments described using specific terms merely illustrate principles and applications of the present disclosure, and various modifications and changes of arrangement are permitted in the embodiments as long as they do not deviate from the spirit of the present disclosure, which is defined by the claims.

### (Supplementary Note)

The following technologies are described in this specification.

### (Item 1)

A gate driver circuit configured to drive a switching circuit including an N-type high-side transistor and an N-type low-side transistor in response to an input signal, the gate driver circuit including:
a bootstrap terminal to which one end of a bootstrap capacitor is connected;
a high-side gate terminal to which a gate of the high-side transistor is connected;
a low-side gate terminal to which a gate of the low-side transistor is connected;
a switching terminal to which an output line of the switching circuit is connected;
a bootstrap switch connected to the bootstrap terminal at one end of the bootstrap switch and configured to receive a constant voltage at the other end of the bootstrap switch;
a high-side driver including an upper power supply terminal connected to the bootstrap terminal and a lower power supply terminal connected to the switching terminal, and configured to generate a high-side gate voltage at the high-side gate terminal in response to a high-side control signal;
a low-side driver configured to generate a low-side gate voltage at the low-side gate terminal in response to a low-side control signal;
a first sensor configured to assert a first detection signal upon detecting a change in an electrical state of a first transistor, which is one of the high-side transistor and the low-side transistor, based on a gate voltage of the first transistor; and
a control circuit configured to generate the high-side control signal and the low-side control signal in response to the input signal and configured to turn on the bootstrap switch in response to the assertion of the first detection signal.

### (Item 2)

The gate driver circuit of Item 1, further including:
a second sensor configured to assert a second detection signal upon detecting a change in an electrical state of a second transistor, which is one of the high-side transistor and the low-side transistor, based on a gate voltage of the second transistor,
wherein the control circuit turns off the bootstrap switch in response to the assertion of the second detection signal.

### (Item 3)

The gate driver circuit of Item 1 or 2, wherein the first sensor compares a gate-source voltage of the low-side transistor with a first threshold voltage.

### (Item 4)

The gate driver circuit of Item 2, wherein the second sensor compares a gate-source voltage of the low-side transistor with a second threshold voltage.

### (Item 5)

The gate driver circuit of Item 1 or 2, wherein the first sensor compares a gate-source voltage of the high-side transistor with a first threshold voltage.

### (Item 6)

The gate driver circuit of Item 2, wherein the second sensor compares a gate-source voltage of the high-side transistor with a second threshold voltage.

### (Item 7)

The gate driver circuit of Item 1 or 2, wherein the first sensor compares a drain-source voltage of the low-side transistor with a first threshold voltage.

### (Item 8)

The gate driver circuit of Item 2, wherein the second sensor compares a drain-source voltage of the low-side transistor with a second threshold voltage.

### (Item 9)

The gate driver circuit of Item 1 or 2, wherein the first sensor compares a drain-source voltage of the high-side transistor with a first threshold voltage.

### (Item 10)

The gate driver circuit of Item 2, wherein the second sensor compares a drain-source voltage of the high-side transistor with a second threshold voltage.

### (Item 11)

A motor driver, including:
a switching circuit including a high-side transistor and a low-side transistor; and
the gate driver circuit of any one of Items 1 to 10 configured to drive the switching circuit.

### (Item 12)

An electronic device, including:
a motor; and
the motor driver of Item 11 configured to drive the motor.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gate driver circuit configured to drive a switching circuit including an N-type high-side transistor and an N-type low-side transistor in response to an input signal, the gate driver circuit comprising:
a bootstrap terminal to which one end of a bootstrap capacitor is connected;
a high-side gate terminal to which a gate of the high-side transistor is connected;
a low-side gate terminal to which a gate of the low-side transistor is connected;
a switching terminal to which an output line of the switching circuit is connected;
a bootstrap switch connected to the bootstrap terminal at one end of the bootstrap switch and configured to receive a constant voltage at the other end of the bootstrap switch;
a high-side driver including an upper power supply terminal connected to the bootstrap terminal and a lower power supply terminal connected to the switching terminal, and configured to generate a high-side gate voltage at the high-side gate terminal in response to a high-side control signal;
a low-side driver configured to generate a low-side gate voltage at the low-side gate terminal in response to a low-side control signal;
a first sensor configured to assert a first detection signal upon detecting a change in an electrical state of a first transistor, which is one of the high-side transistor and the low-side transistor, based on a gate voltage of the first transistor; and
a control circuit configured to generate the high-side control signal and the low-side control signal in response to the input signal and configured to turn on the bootstrap switch in response to the assertion of the first detection signal.

2. The gate driver circuit of claim 1, further comprising:
a second sensor configured to assert a second detection signal upon detecting a change in an electrical state of a second transistor, which is one of the high-side transistor and the low-side transistor, based on a gate voltage of the second transistor,
wherein the control circuit turns off the bootstrap switch in response to the assertion of the second detection signal.

3. The gate driver circuit of claim 1, wherein the first sensor compares a gate-source voltage of the low-side transistor with a first threshold voltage.

4. The gate driver circuit of claim 2, wherein the second sensor compares a gate-source voltage of the low-side transistor with a second threshold voltage.

5. The gate driver circuit of claim 1, wherein the first sensor compares a gate-source voltage of the high-side transistor with a first threshold voltage.

6. The gate driver circuit of claim 2, wherein the second sensor compares a gate-source voltage of the high-side transistor with a second threshold voltage.

7. The gate driver circuit of claim 1, wherein the first sensor compares a drain-source voltage of the low-side transistor with a first threshold voltage.

8. The gate driver circuit of claim 2, wherein the second sensor compares a drain-source voltage of the low-side transistor with a second threshold voltage.

9. The gate driver circuit of claim 1, wherein the first sensor compares a drain-source voltage of the high-side transistor with a first threshold voltage.

10. The gate driver circuit of claim 2, wherein the second sensor compares a drain-source voltage of the high-side transistor with a second threshold voltage.

11. A motor driver, comprising:
a switching circuit including a high-side transistor and a low-side transistor; and
the gate driver circuit of claim 1 configured to drive the switching circuit.

12. An electronic device, comprising:
a motor; and
the motor driver of claim 11 configured to drive the motor.
